(19) United States
(12) Patent Application Publication
(10) Pub. No.: US 2020/0337179 A1
(43) Pub. Date: Oct. 22, 2020

(54) EXPANDABLE HEAT SINK

(71) Applicant: Intel Corporation, Santa Clara, CA (US)

(72) Inventors: Jeff Ku, Taipei (TW); Ming-Che Lee, New Taipei City (TW); Wei-Ming Chu, New Taipei City (TW); Cora Nien, Changhua County (TW)

(73) Assignee: Intel Corporation, Santa Clara, CA (US)

(21) Appl. No.: 16/914,096

(22) Filed: Jun. 26, 2020

(51) Int. Cl. H05K 7/20

(52) U.S. Cl. CPC H05K 7/2039; H05K 7/20172; H05K 7/20336

(57) ABSTRACT

Particular embodiments described herein provide for an expandable heat sink for an electronic device. The expandable heat sink includes flexible thermal conductive material and an activator. The activator can cause the expandable heat sink to be in a retracted configuration with a retracted height or in an expanded configuration with an expanded height, wherein the expanded height is greater than the retracted height. In an example, the flexible thermal conductive material includes graphite sheets.

### TECHNICAL FIELD

This disclosure relates in general to the field of computing and/or device cooling, and more particularly, to an expandable heat sink.

### BACKGROUND

Emerging trends in electronic devices are changing the expected performance and form factor of devices as devices and systems are expected to increase performance and function while having a relatively thin profile. However, the increase in performance and/or function causes an increase in the thermal challenges of the devices and systems. Insufficient cooling can cause a reduction in device performance, a reduction in the lifetime of a device, and delays in data throughput.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1A-1E are a simplified diagram of a system to enable an expandable heat sink, in accordance with an embodiment of the present disclosure;

FIGS. 2A and 2B are a simplified diagram of a partial view of a system to enable an expandable heat sink, in accordance with an embodiment of the present disclosure;

FIGS. 3A and 3B are a simplified diagram of a partial view of a system to enable an expandable heat sink, in accordance with an embodiment of the present disclosure;

FIGS. 4A and 4B are a simplified diagram of a partial view of a system to enable an expandable heat sink, in accordance with an embodiment of the present disclosure;

FIGS. 5A and 5B are a simplified diagram of a partial view of a system to enable an expandable heat sink, in accordance with an embodiment of the present disclosure;

FIGS. 6A and 6B are a simplified diagram of a partial view of a system to enable an expandable heat sink, in accordance with an embodiment of the present disclosure;

FIGS. 7A-7C are a simplified diagram of a partial view of a system to enable an expandable heat sink, in accordance with an embodiment of the present disclosure;

FIGS. 8A and 8B are a simplified diagram of a partial view of a system to enable an expandable heat sink, in accordance with an embodiment of the present disclosure; and

FIG. 9 is a simplified diagram simplified block diagram of a system that includes an expandable heat sink, in accordance with an embodiment of the present disclosure.

The FIGURES of the drawings are not necessarily drawn to scale, as their dimensions can be varied considerably without departing from the scope of the present disclosure.

### DETAILED DESCRIPTION

### Example Embodiments

The following detailed description sets forth examples of apparatuses, methods, and systems relating to enabling an expandable heat sink. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer or component disposed over or under another layer or component may be directly in contact with the other layer or component or may have one or more intervening layers or components. Moreover, one layer or component disposed between two layers or components may be directly in contact with the two layers or components or may have one or more intervening layers or components. In contrast, a first layer or first component “directly on” a second layer or second component is in direct contact with that second layer or second component. Similarly, unless explicitly stated otherwise, one feature disposed between two features may be in direct contact with the adjacent features or may have one or more intervening layers.

Implementations of the embodiments disclosed herein may be formed or carried out on a substrate, such as a non-semiconductor substrate or a semiconductor substrate. In one implementation, the non-semiconductor substrate may be silicon dioxide, an inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

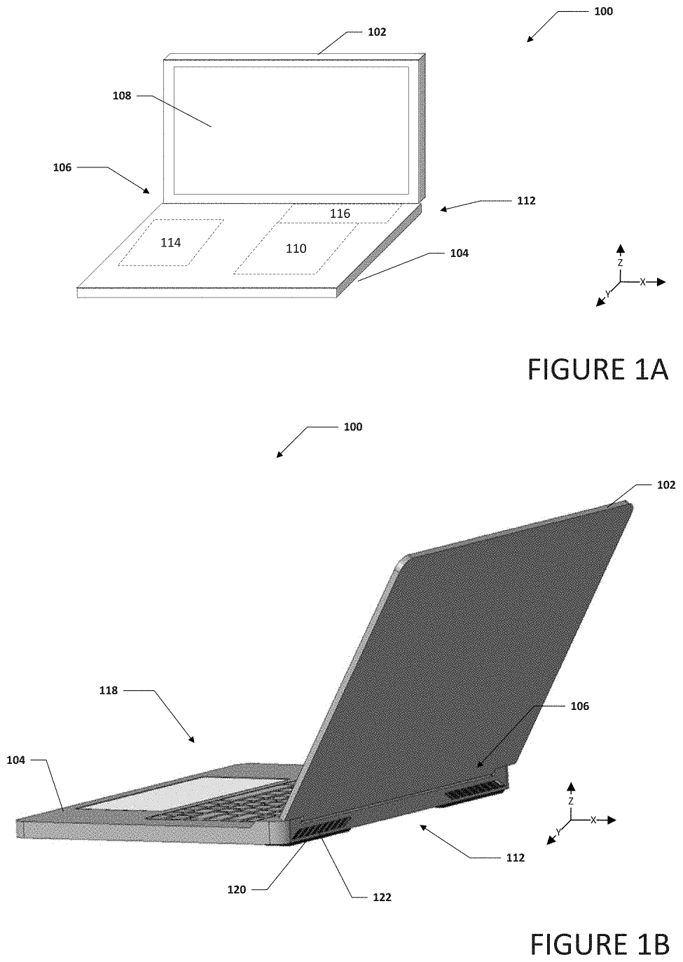

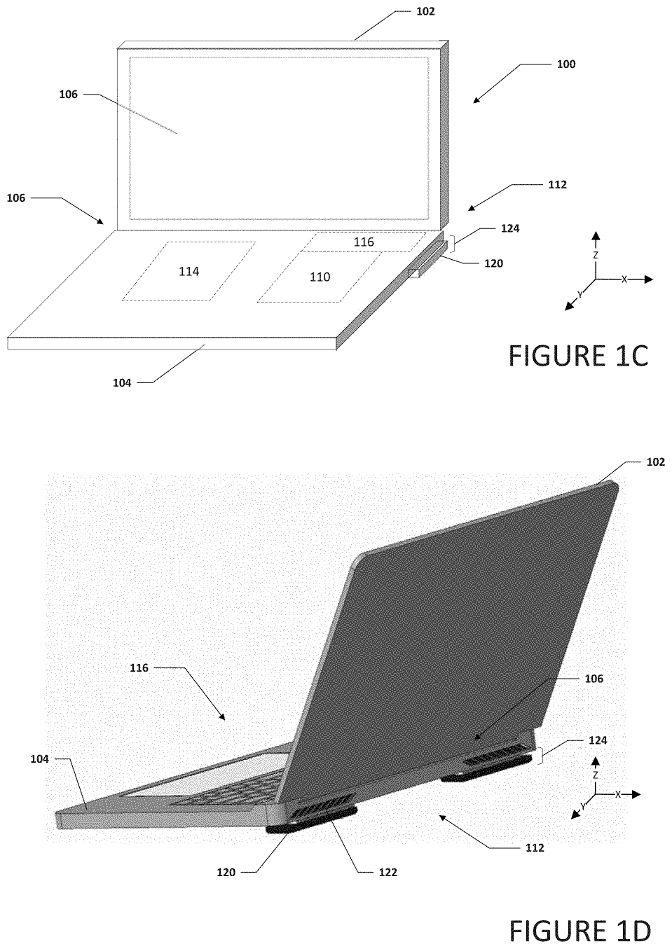

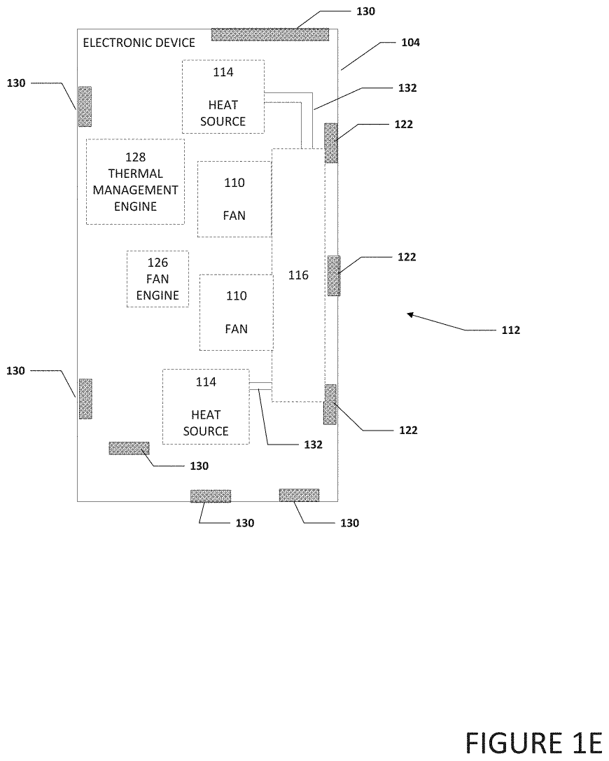

Turning to FIG. 1A, FIG. 1A is a simplified diagram of an electronic device 100 configured with an expandable heat sink, in accordance with an embodiment of the present disclosure. In an example, electronic device 100 can include a first housing 102 and a second housing 104. First housing 102 can be rotatably coupled to second housing 104 using a hinge 106. First housing 102 can include a display 108. Second housing 104 can include a fan 110, an expandable heat sink 112, and one or more heat sources 114. Expandable heat sink 112 can include flexible thermal conductive material 116. Flexible thermal conductive material 116 can be a plurality of graphite sheets, flexible thermal conductive fiber braids (e.g., copper braids, titanium braids, etc.) or some other similar thermal conductive material that is relatively flexible. In some examples, second housing 104 may be a standalone device where there is not a first housing (e.g., a tablet, smartphone, etc.).

Turning to FIG. 1B, FIG. 1B is a simplified diagram of electronic device 100 configured with an expandable heat sink, in accordance with an embodiment of the present disclosure. In an example, electronic device 100 can include first housing 102 and second housing 104. First housing 102 can be rotatably coupled to second housing 104 using hinge 106. Second housing 104 can include expandable heat sink 112, a keyboard 118, feet 120, and vents 122. FIGS. 1A and 1B illustrate when expandable heat sink 112 is in a retracted configuration. In the retracted configuration, second housing 104 has a relatively low cooling capacity.

Turning to FIG. 1C, FIG. 1C is a simplified diagram of an electronic device 100 configured with an expandable heat sink, in accordance with an embodiment of the present disclosure. In an example, electronic device 100 can include first housing 102 and second housing 104. First housing 102 can be rotatably coupled to second housing 104 using hinge 106. First housing 102 can include display 108. Second housing 104 can include fan 110, expandable heat sink 112, and one or more heat sources 114. Expandable heat sink 112 can include flexible thermal conductive material 116.

Turning to FIG. 1D, FIG. 1D is a simplified diagram of electronic device 100 configured with an expandable heat sink, in accordance with an embodiment of the present disclosure. In an example, electronic device 100 can include first housing 102 and second housing 104. First housing 102 can be rotatably coupled to second housing 104 using hinge 106. Second housing 104 can include expandable heat sink 112, keyboard 118, feet 120, and vents 122. As illustrated in FIGS. 1C and 1D, expandable heat sink 112 is raised to an expanded height 124 and expandable heat sink 112 is in an expanded configuration. In the expanded configuration, second housing 104 has a relatively high cooling capacity configuration and the cooling capacity of second housing 104 in the expanded configuration is higher than the cooling capacity of the second housing 104 in the retracted configuration. In a non-limiting illustrative example, expanded height 124 can be greater than three (3) millimeters, greater than four (4) millimeters, greater than about three (3) millimeters and less than about fifteen (15) millimeters, between about four (4) millimeters and about fifteen (15) millimeters, between about five (5) millimeters and about twenty (20) millimeters, between about three (3) millimeters and about one hundred and fifty (150) millimeters, or some other distance depending on design constraints.

Turning to FIG. 1E, FIG. 1E is a simplified partial block diagram of electronic device configured 100 with an expandable heat sink, in accordance with an embodiment of the present disclosure. In an example, second housing 104 can include one or more fans 110, expandable heat sink 112, one or more heat sources 114, vents 122, a fan engine 126, a thermal management engine 128, one or more inlets 130, and one or more heat pipes 132. Expandable heat sink 112 can include flexible thermal conductive material 116. Each of heat pipes 132 may be a heat pipe, vapor chamber, some other heat transfer element that can help transfer heat from each of one or more heat sources 114 to expandable heat sink 112 and more specifically, to flexible thermal conductive material 116.

Each of one or more heat sources 114 may be a heat generating device (e.g., processor, logic unit, field programmable gate array (FPGA), chip set, a graphics processor, graphics card, battery, memory, or some other type of heat generating device). Each one or more fans 110 can be configured as an air-cooling system to move air across flexible thermal conductive material 116 and dissipate heat collected from one or more heat sources 114. Fan engine 126 can be configured to control the velocity or speed of each of fans 110. Thermal management engine 128 can be configured to collect data or thermal parameters related to one or more heat sources 114 and other components, elements, devices (e.g., battery, device or group of devices available to assist in the operation or function of electronic device 100, etc.) in electronic device 100 and communicate the data to fan engine 126. The term “thermal parameters” includes a measurement, range, indicator, etc. of an element or condition that affects the thermal response, thermal state, and/or thermal transient characteristics of the heat source associated with the thermal parameters. The thermal parameters can include a platform workload intensity, a CPU workload or processing speed, a data workload of a neighboring device, fan speed, air temperature (e.g., ambient air temperature, temperature of the air inside the platform, etc.), power dissipation of the device, or other indicators that may affect the thermal condition of second housing 104.

In an example, expandable heat sink 112 can help increase the cooling capability of electronic device 100 without increasing system Z height when increased cooling is not needed. The term “Z height,” “Z location,” etc. refers to the height along the “Z” axis of an (x, y, z) coordinate axis or cartesian coordinate system. More specifically, expandable heat sink 112 can include flexible thermal conductive material 116. When expandable heat sink 112 expands, as illustrated in FIGS. 1C and 1D, the expansion increases the surface area of flexible thermal conductive material 116 and increases the amount of heat that can be dissipated. The expansion of expandable heat sink 112 can be activated mechanically (e.g., switch, button, lever, etc.), electrically, with shape memory material, or by some other means. When expandable heat sink 112 is retracted, as illustrated in FIGS. 1A and 1B, expandable heat sink 112 can be relatively flush to the chassis of second housing 104 without increasing the Z height of second housing 104 or electronic device 100.

In an example, flexible thermal conductive material 116 in expandable heat sink 112 is composed of graphite sheets, copper braids, or some other similar thermal conductive material that is relatively flexible. Flexible thermal conductive material 116 can be coupled to one or more heat pipes 132. When the expansion of expandable heat sink 112 is activated (e.g., mechanically, electrically, with shape memory material, etc.), expandable heat sink 112 is raised to an expanded height 124 exposing flexible thermal conductive material 116 and expandable heat sink 112 is in an expanded configuration and has increased cooling capacity. When expandable heat sink 112 is deactivated, expandable heat sink 112 is not expanded and expandable heat sink 112 retracts it back to the retracted configuration and can be relatively flush to the chassis of second housing 104 without increasing the Z height of second housing 104 or electronic device 100.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur. Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment.

It is to be understood that other embodiments may be utilized and structural changes may be made without departing from the scope of the present disclosure. Substantial flexibility is provided in that any suitable arrangements and configuration may be provided without departing from the teachings of the present disclosure.

For purposes of illustrating certain example techniques, the following foundational information may be viewed as a basis from which the present disclosure may be properly explained. End users have more media and communications choices than ever before. A number of prominent technological trends are currently afoot (e.g., more computing elements, more online video services, more Internet traffic, more complex processing, etc.), and these trends are changing the expected performance and form factor of devices as devices and systems are expected to increase performance and function while having a relatively thin profile. However, the increase in performance and/or function causes an increase in the thermal challenges of the devices and systems. For example, in some devices, it can be difficult to cool a particular heat source. One of the most common solutions to address the thermal challenges of devices and systems is to use a fan and a heat sink.

However, the volume of some current thermal solutions composed of fan, heat sinks, and heat pipe/vapor chamber is insufficient due to a need to bring the total thickness of electronic devices, especially high-performance computing mobile devices, lower and reduce the Z height of the electronic devices. One of the biggest issues when system thickness is reduced is mainly due to a lack of space for thermal solutions. Typically, the fins on a heat sink are made of copper or aluminum, mounted perpendicularly to a heat pipe or vapor chamber. This design is rigid and, due to the need for a relatively low Z-height, the height of the fins cannot be increased to increase cooling capacity.

Some systems use a cooling pad to try and help provide additional cooling for the electronic device. However, cooling pads typically only cool the bottom surface of the electronic device. Because there are typically not any thermal vents on the bottom surface of the electronic device where the cooling pad is in contact with the electronic device, the internal components of the electronic device are not cooled as directly as they are with a heat pipe. Also, cooling pads do not dissipate from the heat sources directly as there's no airflow going through the heat sink directly. What is needed is a means, system, apparatus, method, etc. of increasing the cooling capacity of an electronic device when increased cooling is needed.

A system to enable an expandable heat sink, as outlined in FIG. 1, can resolve these issues (and others). In an example, an expandable heat sink can replace the rigid solid copper or aluminum fins on a heat sink and, when needed, allow the total length of the fins to be longer and denser compared to some current heat sinks. This increases the cooling capability of electronic devices, especially thin high-powered laptops when increased cooling is needed without increasing system Z height when increased cooling is not needed. The expandable heat sink can include flexible thermal conductive material. The flexible thermal conductive material can be a graphite sheet, copper braid, or some other similar thermal conductive material that is relatively flexible.

When the expandable heat sink is activated, the expandable heat sink expands from a retracted configuration with a relatively low cooling capacity, as illustrated in FIGS. 1A and 1B to an expanded configuration with a relatively high cooling capacity, as illustrated in FIGS. 1C and 1D. The expandable heat sink can be activated mechanically (e.g., switch, button, lever, etc.), electrically, with shape memory material, or by some other means. When the expandable heat sink is retracted, as illustrated in FIGS. 1A and 1B, the expandable heat sink can be relatively flush to the chassis of the electronic device.

In a specific example, when electronic device is powered on, a motor automatically activates (e.g., without user input or without requiring the user to activate the motor) and causes the expandable heat sink to open to an activated position and the flexible thermal conductive material to become about perpendicular to the heat pipe. When the expandable heat sink is in the expanded configuration, the system becomes elevated (if the system is on a flat surface) and the total surface area of the flexible thermal conductive material can be increased, bringing an increase on the thermal volume. In an example, external fans on a cooling dock can cool the internal heat sink directly by having the airflow generated by the cooling dock going through the heat sink, cooling the heat generated from heat sources directly instead of blowing air on the chassis only. When the system is powered off and the expandable heat sink is returned to its original folded position in the retracted configuration and the expandable heat sink is relatively flushed to the chassis without increasing system Z height.

In an example, electronic device 100 is meant to encompass a computer, a personal digital assistant (PDA), a laptop or electronic notebook, a cellular telephone, an iPhone, a tablet, an IP phone, network elements, network appliances, servers, routers, switches, gateways, bridges, load balancers, processors, modules, or any other device, component, element, or object that includes a heat source. Electronic device 100 may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. Electronic device 100 may include virtual elements.

In regards to the internal structure, electronic device 100 can include memory elements for storing information to be used in the operations outlined herein. Electronic device 100 may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received could be provided in any database, register, queue, table, cache, control list, or other storage structure, all of which can be referenced at any suitable timeframe. Any such storage options may also be included within the broad term ‘memory element’ as used herein.

In certain example implementations, the functions outlined herein may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for the operations described herein. This includes the memory elements being able to store software, logic, code, or processor instructions that are executed to carry out the activities described herein.

In an example implementation, electronic device 100 may include software modules (e.g., fan engine 126, thermal management engine 128, etc.) to achieve, or to foster, operations as outlined herein. These modules may be suitably combined in any appropriate manner, which may be based on particular configuration and/or provisioning needs. In example embodiments, such operations may be carried out by hardware, implemented externally to these elements, or included in some other network device to achieve the intended functionality. Furthermore, the modules can be implemented as software, hardware, firmware, or any suitable combination thereof. These elements may also include software (or reciprocating software) that can coordinate with other network elements in order to achieve the operations, as outlined herein.

Additionally, heat source 114 may be or include one or more processors that can execute software or an algorithm to perform activities as discussed herein. A processor can execute any type of instructions associated with the data to achieve the operations detailed herein. In one example, the processors can transform an element or an article (e.g., data) from one state or thing to another state or thing. In another example, the activities outlined herein may be implemented with fixed logic or programmable logic (e.g., software/computer instructions executed by a processor) and the elements identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

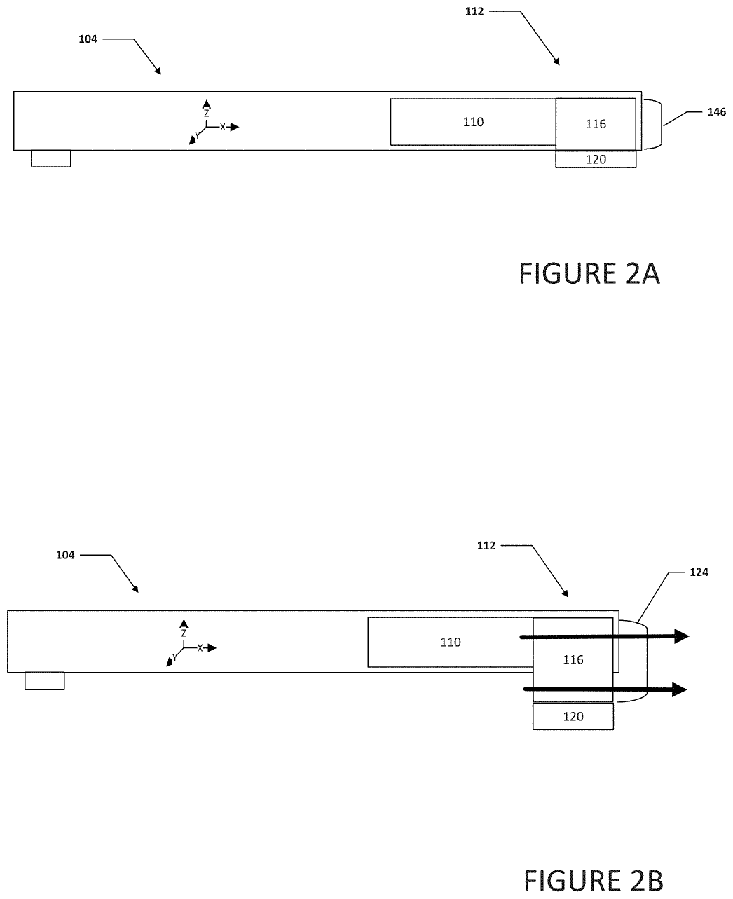

Turning to FIG. 2A, FIG. 2A is a simplified block diagram of a portion of second housing 104. Second housing 104 can include fan 110, expandable heat sink 112, and feet 120. Expandable heat sink 112 can include flexible thermal conductive material 116. When expandable heat sink 112 is not expanded and in a retracted configuration, expandable heat sink 112 can have a retracted height 146 and be relatively flush to the chassis of second housing 104 without increasing the Z height of second housing 104 or electronic device 100 when increased cooling is not needed. In a non-limiting illustrative example, retracted height 146 can be about three (3) millimeters, about four (4) millimeters, between about three (3) millimeters and about five (5) millimeters, less than six (6) millimeters, or some other distance depending on design constraints.

Turning to FIG. 2B, FIG. 2B is a simplified block diagram of a portion of second housing 104. Second housing 104 can include fan 110, expandable heat sink 112, and feet 120. Expandable heat sink 112 can include flexible thermal conductive material 116. When expandable heat sink 112 is expanded. This allows the total area of flexible thermal conductive material 116 to be increased and helps to increase the cooling capability of electronic device 100 when increased cooling is needed.

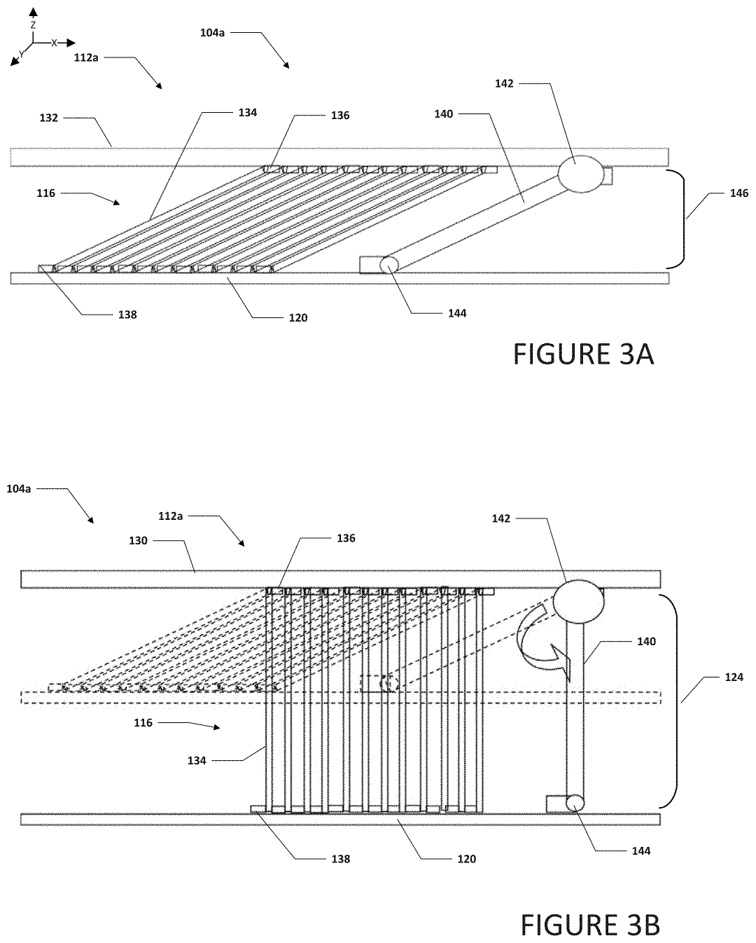

Turning to FIG. 3A, FIG. 3A is a simplified block diagram of a portion of a second housing 104a. Second housing 104a can include an expandable heat sink 112a, feet 120, and heat pipe 132. Expandable heat sink 112a can include flexible thermal conductive material 116 and link mechanism 140. Flexible thermal conductive material 116 can be comprised of a plurality of fins 134. Each of plurality of fins can be a graphite sheet, copper braid, or some other similar thermal conductive material that is relatively flexible. A first end of each of plurality of fins 134 can be thermally coupled to heat pipe 132. For example, the first end of each of plurality of fins 134 can be coupled to heat pipe 132 using a thermal interface material (TIM), a thermal glue, soldered, or any other means that can secure a fin 134 to heat pipe 132 and help allow heat to transfer from heat pipe 132 to fin 134. In addition, a second end of each of the plurality of fins 134 can be coupled to feet 120. In an example, the second end of each of plurality of fins 134 can be coupled to feet 120 using an insulating material to help prevent feet 120 from becoming too hot and causing discomfort or injury to a user if a user were to touch feet 120.

A first end of link mechanism 140 can be coupled to a link mechanism activator 142. A second end of link mechanism 140 can be coupled to a pivot 144. Pivot 144 can be coupled to feet 120. While link mechanism activator 142 is illustrated as being coupled to heat pipe 132 and pivot 144 is illustrated as being coupled to feet 120, link mechanism activator 142 and pivot 144 may be located in any other location that will allow link mechanism activator 142 and pivot 144 to cause link mechanism 140 to expand and retract expandable heat sink 112a. Link mechanism activator 142 can be a step motor, gear transfer motor, or some other motor that may be activated by fan engine 126 to expand and retract expandable heat sink 112a. In other examples, link mechanism activator 142 may be a purely mechanical device (e.g., a spring-loaded mechanism, lever, etc.) where a user manually activates link mechanism activator 142 to expand and retract expandable heat sink 112a. When expandable heat sink 112a is retracted, expandable heat sink 112a can have a retracted height 146 and be relatively flush to the chassis of second housing 104a, as illustrated in FIGS. 1A and 1B, without increasing the Z height of second housing 104a and/or the electronic device that includes expandable heat sink 112a when increased cooling is not needed.

Turning to FIG. 3B, FIG. 3B is a simplified block diagram of a portion of second housing 104a. Second housing 104a can include expandable heat sink 112a, feet 120, and heat pipe 132. Expandable heat sink 112a can include flexible thermal conductive material 116 and link mechanism 140. Flexible thermal conductive material 116 can be comprised of plurality of fins 134. The first end of each of plurality of fins 134 can be thermally coupled to heat pipe 132. In addition, the second end of each of plurality of fins 134 can be coupled to feet 120.

The first end of link mechanism 140 can be coupled to link mechanism activator 142. The second end of link mechanism 140 can be coupled to pivot 144. Pivot 144 can be coupled to feet 120. While link mechanism activator 142 is illustrated as being coupled to heat pipe 132 and pivot 144 is illustrated as being coupled to feet 120, link mechanism activator 142 and pivot 144 may be located in any other location that will allow link mechanism activator 142 and pivot 144 to cause link mechanism 140 to expand and retract expandable heat sink 112a. When expandable heat sink 112a is expanded, expandable heat sink 112a can have an expanded height 124 and the distance between each of plurality of fins 134 is increased. This allows the area of flexible thermal conductive material 116 to be increased and helps to increase the cooling capability of second housing 104a and/or the electronic device that includes expandable heat sink 112a when increased cooling is needed.

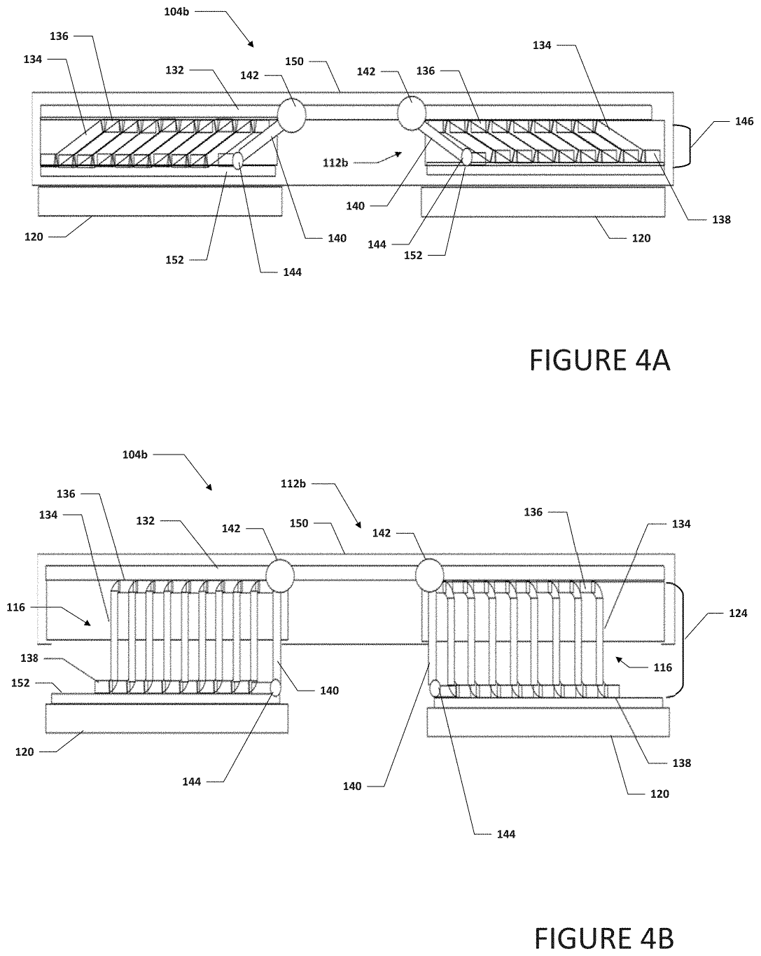

Turning to FIG. 4A, FIG. 4A is a simplified block diagram of a portion of second housing 104b. Second housing 104b can include an expandable heat sink 112b, feet 120, heat pipe 132, a top chassis 150, and support layer 152. Expandable heat sink 112b can include flexible thermal conductive material 116 and link mechanism 140. Flexible thermal conductive material 116 can be comprised of a plurality of fins 134. A first end of each of plurality of fins 134 can be thermally coupled to heat pipe 132. For example, the first end of each of plurality of fins 134 can be coupled to heat pipe 132 using a thermal interface material (TIM), a thermal glue, soldered, or any other means that can secure a fin 134 to heat pipe 132 and help allow heat to transfer from heat pipe 132 to fin 134. In addition, a second end of each of plurality of fins 134 can be coupled to support layer 152 over feet 120. In an example, the second end of each of plurality of fins 134 can be coupled to support layer 152 over feet 120 using an insulating material to help prevent feet 120 from becoming too hot and causing discomfort or injury to a user if a user were to touch feet 120. In addition, supporting layer 152 may have insulating properties to help prevent heat from plurality of fins 134 from being transferred to feet 120.

A first end of link mechanism 140 can be coupled to link mechanism activator 142. A second end of link mechanism 140 can be coupled to pivot 144. Pivot 144 can be coupled to support layer 152. While link mechanism activator 142 is illustrated as being coupled to top chassis 150 and pivot 144 is illustrated as being coupled to support layer 152, link mechanism activator 142 and pivot 144 may be located in any other location that will allow link mechanism activator 142 and pivot 144 to cause link mechanism 140 to expand and retract expandable heat sink 112b. When expandable heat sink 112b is retracted, expandable heat sink 112b can have a retracted height 146 and be relatively flush to the chassis of second housing 104b, as illustrated in FIGS. 1A and 1B, without increasing the Z height of second housing 104b and/or the electronic device that includes expandable heat sink 112b when increased cooling is not needed.

Turning to FIG. 4B, FIG. 4B is a simplified block diagram of a portion of second housing 104b. Second housing 104b can include expandable heat sink 112b, feet 120, heat pipe 132, top chassis 150, and support layer 152. Expandable heat sink 112b can include flexible thermal conductive material 116 and link mechanism 140. Flexible thermal conductive material 116 can be comprised of plurality of fins 134. A first end of each of plurality of fins 134 can be thermally coupled to heat pipe 132. In addition, the second end of each of plurality of fins 134 can be coupled to support layer 152 over feet 120.

The first end of link mechanism 140 can be coupled to link mechanism activator 142. The second end of link mechanism 140 can be coupled to pivot 144. Pivot 144 can be coupled to feet 120. While link mechanism activator 142 is illustrated as being coupled to top chassis 150 and pivot 144 is illustrated as being coupled to support layer 152, link mechanism activator 142 and pivot 144 may be located in any other location that will allow link mechanism activator 142 and pivot 144 to cause link mechanism 140 to expand and retract expandable heat sink 112b. When expandable heat sink 112b is expanded, expandable heat sink 112b can have an expanded height 124 and the distance between each of plurality of fins 134 is increased. This allows the area of flexible thermal conductive material 116 to be increased and helps to increase the cooling capability of second housing 104b and/or the electronic device that includes expandable heat sink 112b when increased cooling is needed.

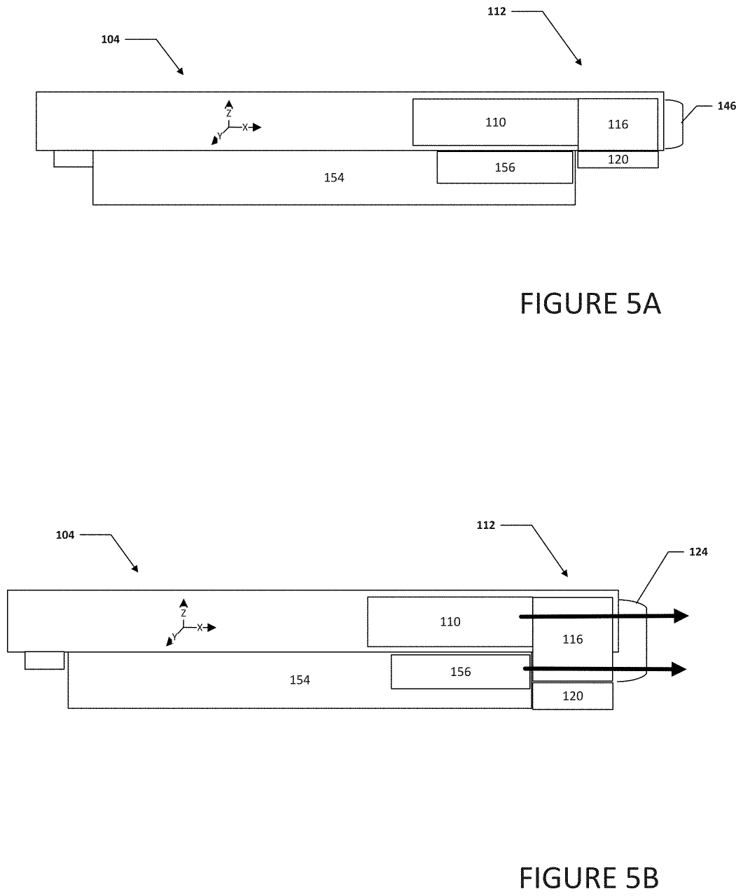

Turning to FIG. 5A, FIG. 5A is a simplified block diagram of a portion of a second housing 104. Second housing 104 can include fan 110, expandable heat sink 112, and feet 120. Expandable heat sink 112 can include flexible thermal conductive material 116. In an example, second housing 104 can be over a cooling dock 154. Cooling dock 154 can include cooling dock fan 156. Cooling dock 154 can be a removable cooling dock or cooling pad. When expandable heat sink 112 is retracted, expandable heat sink 112 can have a retracted height 146 and be relatively flush to the chassis of second housing 104 without increasing the Z height of second housing 104 and/or electronic device 100 when increased cooling is not needed.

Turning to FIG. 5B, FIG. 5B is a simplified block diagram of a portion of second housing 104. Second housing 104 can include fan 110, expandable heat sink 112, and feet 120. Expandable heat sink 112 can include flexible thermal conductive material 116. In an example, second housing 104 can be over cooling dock 154. Cooling dock 154 can include cooling dock fan 156. When expandable heat sink 112 is expanded, expandable heat sink 112 can have an expanded height 124 and the distance between each of plurality of fins 134 is increased. This allows the area of flexible thermal conductive material 116 to be increased and helps to increase the cooling capability of second housing 104 and/or electronic device 100 when increased cooling is needed. Cooling dock fan 156 can help remove heat collected by expandable heat sink 112 to provide additional cooling.

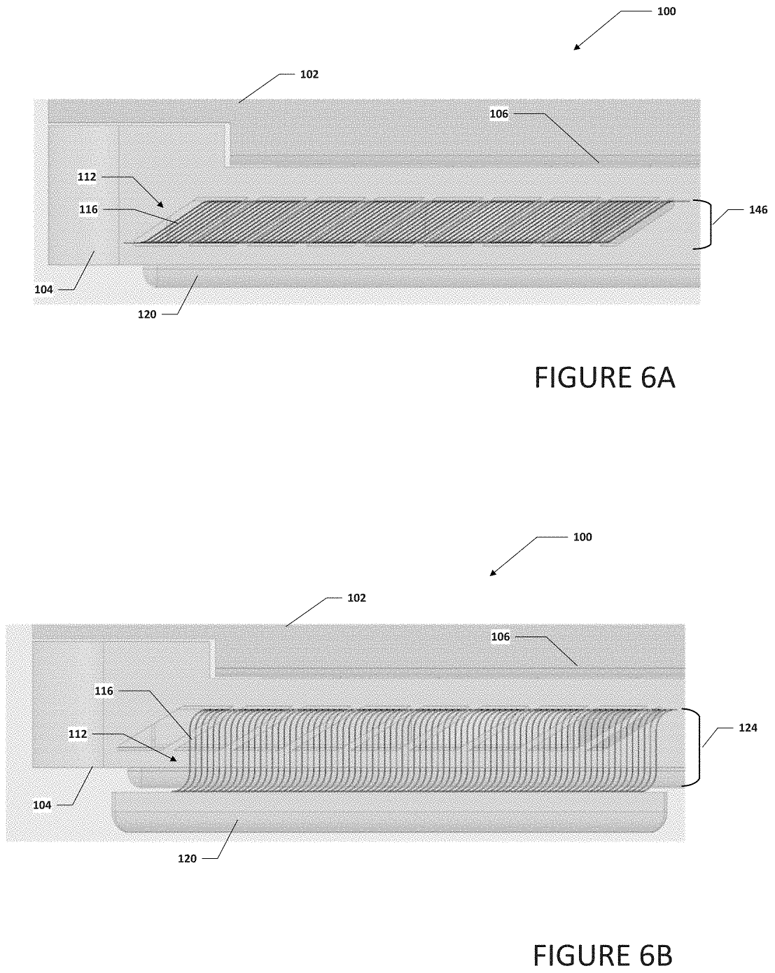

Turning to FIG. 6A, FIG. 6A is a simplified block diagram of a portion of electronic device 100. Electronic device can include first housing 102 and second housing 104. First housing 102 can be rotatably coupled to second housing 104 using hinge 106. Second housing 104 can include expandable heat sink 112 and feet 120. Expandable heat sink 112 can include flexible thermal conductive material 116. When expandable heat sink 112 is retracted, expandable heat sink 112 can have a retracted height 146 and be relatively flush to the chassis of second housing 104 without increasing the Z height of second housing 104 and/or electronic device 100 when increased cooling is not needed.

Turning to FIG. 6B, FIG. 6B is a simplified block diagram of a portion of electronic device 100. Electronic device can include first housing 102 and second housing 104. First housing 102 can be rotatably coupled to second housing 104 using hinge 106. Second housing 104 can include expandable heat sink 112 and feet 120. Expandable heat sink 112 can include flexible thermal conductive material 116. When expandable heat sink 112 is expanded, expandable heat sink 112 can have an expanded height 124 exposing flexible thermal conductive material 116. This allows the total surface area of flexible thermal conductive material 116 to be increased and help increase the cooling capability of second housing and/or electronic device 100 when increased cooling is needed. The length of expanded height 124 is limited at least by design choice and the material in flexible thermal conductive material 116. For example, if flexible thermal conductive material 116 is a graphite spreader, then a bend radius of the graphite spreader needs to be at or below a maximum bend radius for the graphite spreader.

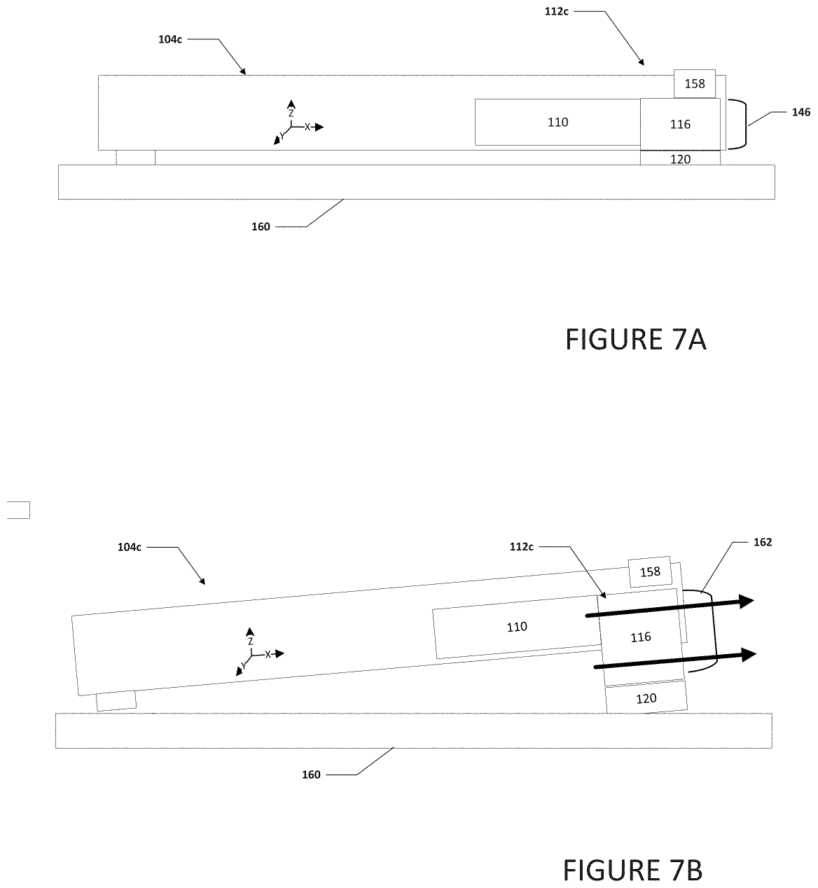

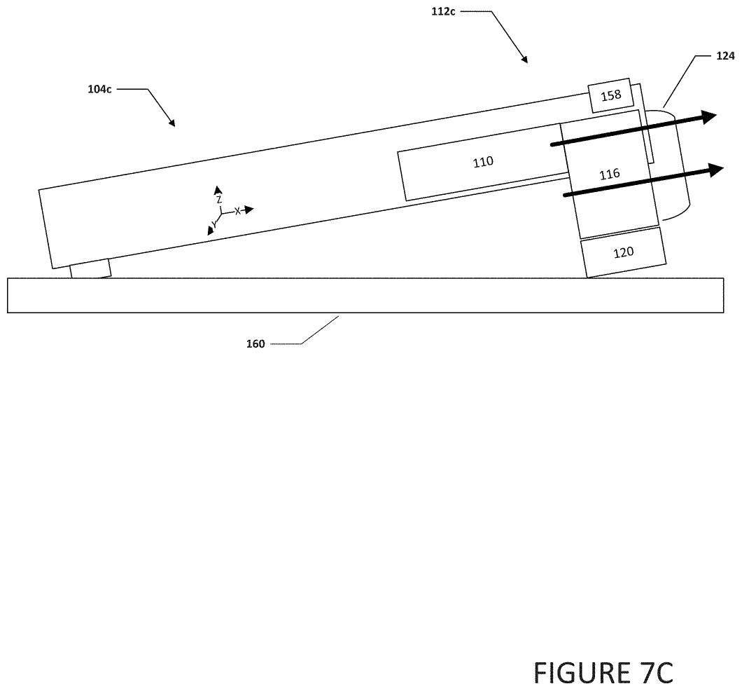

Turning to FIG. 7A, FIG. 7A is a simplified block diagram of a portion of a second housing 104c. Second housing 104c can include fan 110, an expandable heat sink 112c, feet 120, and a user activation mechanism 158. Expandable heat sink 112c can include flexible thermal conductive material 116. In an example, user activation mechanism 158 may be an electrical switch, button, knob, or some other user input device that when activated by the user, expands or retracts expandable heat sink 112c. The activation of user activation mechanism 158 by the user can send a signal to fan engine 126 to expand or retract expandable heat sink 112c. In another example, user activation mechanism 158 may be a switch, lever, knob, or some other mechanical user input device that when activated by the user, expands or retracts expandable heat sink 112c. When expandable heat sink 112c is retracted, the height of expandable heat sink 112c can be retracted height 146 and expandable heat sink 112c can be relatively flush to the chassis of second housing 104c without increasing the Z height of second housing 104c and/or the electronic device that includes expandable heat sink 112c. In addition, when expandable heat sink 112c is retracted, second housing 104c can set relatively flat on or parallel with a surface 160. Surface 160 may be the surface of a table or desk.

Turning to FIG. 7B, FIG. 7B is a simplified block diagram of a portion of second housing 104c. Second housing 104c can include fan 110, expandable heat sink 112c, feet 120, and user activation mechanism 158. Expandable heat sink 112c can include flexible thermal conductive material 116. In an example, expandable heat sink 112c can raise to more than two different heights. For example, as illustrated in FIG. 7B, expandable heat sink 112c has been expanded or raised to an intermediate height 162. In some examples, user activation mechanism 158 can have different settings (e.g., knobs on a dial to designate a selected height). In other examples, thermal management engine 128 can monitor the thermal characteristics of second housing 104b and raise or expand expandable heat sink 112c to a level that will help allow second housing 104b to cool down. When expandable heat sink 112c is expanded to intermediate height 162, the area of flexible thermal conductive material 116 is increased and helps to increase the cooling capability of second housing 104c and/or the electronic device that includes expandable heat sink 112c when increased cooling is needed.

Turning to FIG. 7C, FIG. 7C is a simplified block diagram of a portion of second housing 104c. Second housing 104c can include fan 110, expandable heat sink 112c, feet 120, and user activation mechanism 158. Expandable heat sink 112c can include flexible thermal conductive material 116. In an example, expandable heat sink 112c can raise to more than two different heights. For example, as illustrated in FIG. 7C, expandable heat sink 112c has been expanded or raise to expanded height 124. In some examples, user activation mechanism 158 can have different settings (e.g., knobs on a dial to designate a selected height). In other examples, thermal management engine 128 can monitor the thermal characteristics of second housing 104c and raise or expand expandable heat sink 112c to a level that will help allow second housing 104c to cool down. When expandable heat sink 112c is expanded to expanded height 124, the area of flexible thermal conductive material 116 is increased and helps to increase the cooling capability of second housing 104c when increased cooling is needed.

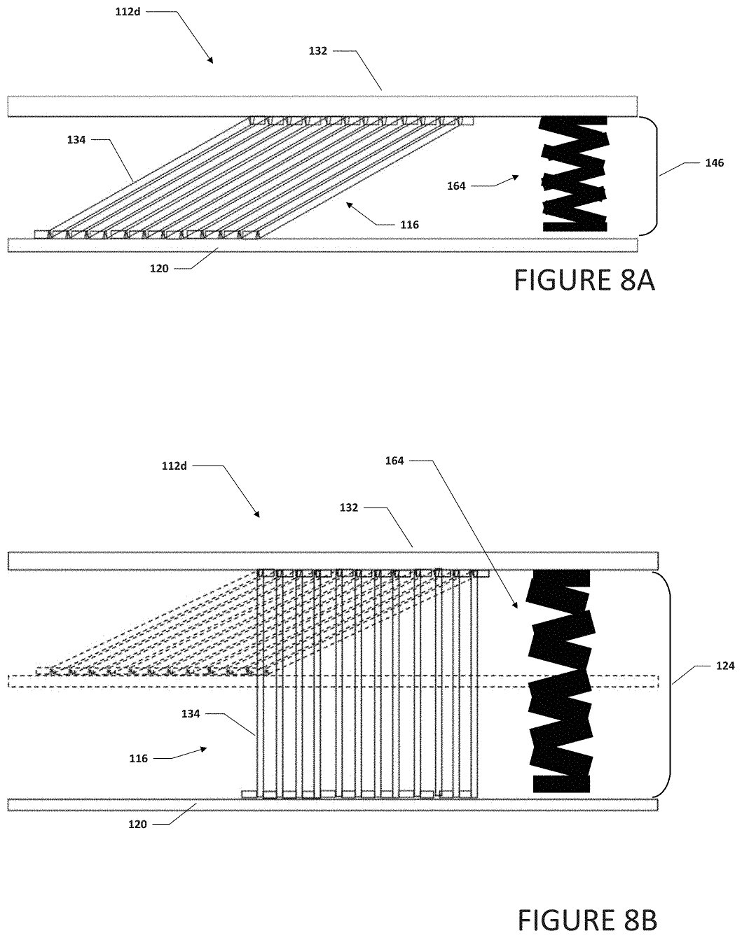

Turning to FIG. 8A, FIG. 8A is a simplified block diagram of a portion of expandable heat sink 112d. Expandable heat sink 112d can include flexible thermal conductive material 116 and temperature-controlled activator 164. Flexible thermal conductive material 116 can be comprised of plurality of fins 134. A first end of each of plurality of fins 134 can be thermally coupled to heat pipe 132. In addition, a second end of each of plurality of fins 134 can be coupled to feet 120. While temperature-controlled activator 164 is illustrated as being coupled to heat pipe 132 and to feet 120, temperature-controlled activator 164 may be located in any other location that will allow temperature-controlled activator 164 to expand and retract expandable heat sink 112d. Temperature-controlled activator 164 can be a shape memory material, or some other material or mechanism that may be activated by heat. If temperature-controlled activator 164 is a shape memory material, it can be tuned virtue of the shape memory effect (SME) or shape memory “temperatures” that are selected for the shape memory material. One type of shape memory material that may be used is a Nickel-Titanium alloy (“Nitinol”). When expandable heat sink 112d is retracted, expandable heat sink 112d can have a retracted height 146 and be relatively flush to the chassis (e.g., the chassis of second housing 104a, as illustrated in FIGS. 1A and 1B,) without increasing the Z height of the electronic device that includes expandable heat sink 112d when increased cooling is not needed.

Turning to FIG. 8B, FIG. 8B is a is a simplified block diagram of a portion of expandable heat sink 112d. Expandable heat sink 112d can include flexible thermal conductive material 116 and temperature-controlled activator 164. Flexible thermal conductive material 116 can be comprised of a plurality of fins 134. A first end of each of plurality of fins 134 can be thermally coupled to heat pipe 132. In addition, a second end of each of plurality of fins 134 can be coupled to feet 120. While temperature-controlled activator 164 is illustrated as being coupled to heat pipe 132 and to feet 120, temperature-controlled activator 164 may be located in any other location that will allow temperature-controlled activator 164 to expand and retract expandable heat sink 112d. When a temperature of temperature-controlled activator 164 reaches a threshold temperature, temperature-controlled activator 164 can expand and expandable heat sink 112d is expanded to expanded height 124. This allows the area of flexible thermal conductive material 116 to be increased and the distance between each of plurality of fins 134 to increase and help increase the cooling capability of expandable heat sink 112d when increased cooling is needed. When a temperature of temperature-controlled activator 164 is below the threshold temperature, temperature-controlled activator 164 can retract and return to the configuration illustrated in FIG. 8A. This allows the total surface area of flexible thermal conductive material 116 to be increased when the temperature of temperature-controlled activator 164 and the surrounding environment reaches a threshold to help increase the cooling capability of expandable heat sink 112d and for expandable heat sink 112d to return to a retracted configuration when the temperature of temperature-controlled activator 164 and the surrounding environment is below the threshold and addition cooling is not needed.

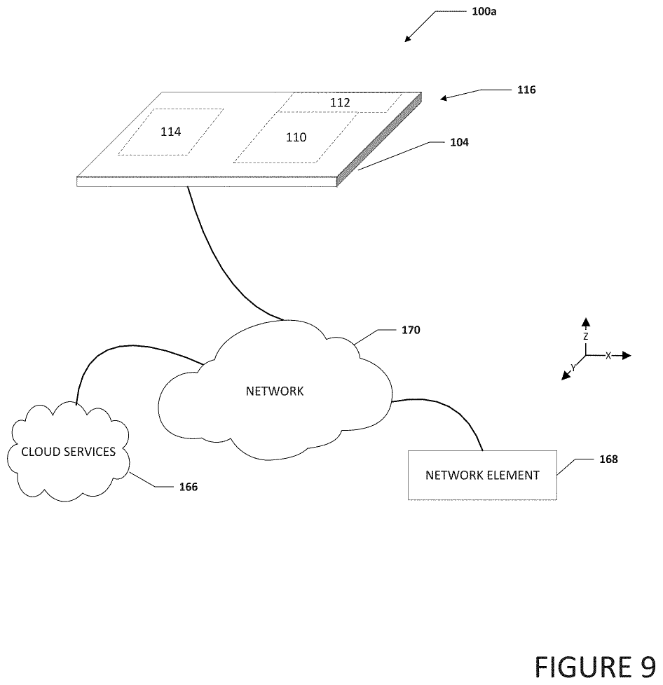

Turning to FIG. 9, FIG. 9 is a simplified block diagram of a portion of an electronic device 100a configured to include an expandable heat sink. In an example, electronic device 100a can include fan 110, expandable heat sink 112, and heat source 114. Electronic device 100a may be a handheld device, a tablet, smartphone, or other similar device that includes a fan and a heat source. Electronic device 100a may be in communication with cloud services 166 and/or network element 168 using network 170. In an example, electronic device 100a is a standalone device and not connected to network 170.

Elements of FIG. 9 may be coupled to one another through one or more interfaces employing any suitable connections (wired or wireless), which provide viable pathways for network (e.g., network 170, etc.) communications. Additionally, any one or more of these elements of FIG. 9 may be combined or removed from the architecture based on particular configuration needs. Network 170 may include a configuration capable of transmission control protocol/Internet protocol (TCP/IP) communications for the transmission or reception of packets in a network. Electronic device 100a may also operate in conjunction with a user datagram protocol/IP (UDP/IP) or any other suitable protocol where appropriate and based on particular needs.

Turning to the infrastructure of FIG. 9, network 170 represents a series of points or nodes of interconnected communication paths for receiving and transmitting packets of information. Network 170 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In network 170, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks. The data may help determine a status of a network element or network. Additionally, messages, requests, responses, and queries are forms of network traffic, and therefore, may comprise packets, frames, signals, data, etc.

Although the present disclosure has been described in detail with reference to particular arrangements and configurations, these example configurations and arrangements may be changed significantly without departing from the scope of the present disclosure. Moreover, certain components may be combined, separated, eliminated, or added based on particular needs and implementations. For example, electronic device 100 may include two or more fans 110 and/or two or more expandable heat sinks 112 with each fan 110 and expandable heat sink 112 being independently controlled by thermal management engine 128 or controlled as a unit or group. Additionally, although electronic device 100 has been illustrated with reference to particular elements and operations that facilitate the thermal cooling process, these elements and operations may be replaced by any suitable architecture, protocols, and/or processes that achieve the intended functionality disclosed herein.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### Other Notes and Examples

In Example A1, an expandable heat sink for an electronic device includes flexible thermal conductive material and an activator. The activator can cause the expandable heat sink to be in a retracted configuration with a retracted height or in an expanded configuration with an expanded height, where the expanded height is greater than the retracted height.

In Example A2, the subject matter of Example A1 can optionally include where the activator is a link mechanism activator coupled to a link mechanism.

In Example A3, the subject matter of any one of Examples A1-A2 can optionally include where the link mechanism activator is a motor.

In Example A4, the subject matter of any one of Examples A1-A3 can optionally include where the flexible thermal conductive material includes graphite sheets.

In Example A5, the subject matter of any one of Examples A1-A4 can optionally include where the flexible thermal conductive material is coupled to a heat pipe.

In Example A6, the subject matter of any one of Examples A1-A5 can optionally include where the retracted height is about three (3) millimeters and the expanded height is greater than about three (3) millimeters.

Example AA1 is a device including one or more heat sources, one or more fans, and one or more expandable heat sinks. Each of the one or more expandable heat sinks can include flexible thermal conductive material and an activator. The activator can cause the expandable heat sink to be in a retracted configuration with a retracted height or in an expanded configuration with an expanded height, where the expanded height is greater than the retracted height.

In Example AA2, the subject matter of Example AA1 can optionally include where the retracted height is about three (3) millimeters and the expanded height is greater than about three (3) millimeters and less than about fifteen (15) millimeters.

In Example AA3, the subject matter of any one of the Examples AA1-AA2 can optionally include where the flexible thermal conductive material includes graphite sheets.

In Example AA4, the subject matter of any one of the Examples AA1-AA3 can optionally include where the flexible thermal conductive material includes fiber braids.

In Example AA5, the subject matter of any one of the Examples AA1-AA4 can optionally include a cooling dock, where the cooling dock includes a cooling dock fan to move air through the one or more expandable heat sinks in the expanded configuration.

In Example AA6, the subject matter of any one of the Examples AA1-AA5 can optionally include where the flexible thermal conductive material is coupled to a heat pipe.

In Example AA7, the subject matter of any one of the Examples AA1-AA6 can optionally include where the activator is a link mechanism activator coupled to a link mechanism.

In Example AA8, the subject matter of any one of the Examples AA1-AA7 can optionally include where the link mechanism activator is a step motor.

Example M1 is a method including activating an activator to cause the expandable heat sink to be in an expanded configuration and deactivating the activator to cause the expandable heat sink to be in a retracted configuration, where the expandable heat sink includes flexible thermal conductive material.

In Example M2, the subject matter of Example M1 can optionally include where a retracted height of the expandable heat sink in the retracted configuration is about three (3) millimeters and an expanded height of the expandable heat sink in the expanded configuration is greater than about three (3) millimeters.

In Example M3, the subject matter of any one of the Examples M1-M2 can optionally include where the flexible thermal conductive material includes graphite sheets.

In Example M4, the subject matter of any one of the Examples M1-M3 can optionally include where the flexible thermal conductive material is coupled to a heat pipe.

In Example M5, the subject matter of any one of the Examples M1-M4 can optionally include where the activator is a link mechanism activator coupled to a link mechanism.

In Example M6, the subject matter of any one of the Examples M1-M5 can optionally include where the link mechanism activator is a step motor.

Example AAA1 is an apparatus including means for activating an activator to cause the expandable heat sink to be in an expanded configuration and means for deactivating the activator to cause the expandable heat sink to be in a retracted configuration, where the expandable heat sink includes flexible thermal conductive material.

In Example AAA2, the subject matter of Example AAA1 can optionally include where a retracted height of the expandable heat sink in the retracted configuration is about three (3) millimeters and an expanded height of the expandable heat sink in the expanded configuration is greater than about three (3) millimeters.

In Example AAA3, the subject matter of any one of Examples AAA1-AAA2 can optionally include where the flexible thermal conductive material includes graphite sheets.

In Example AAA4, the subject matter of any one of Examples AAA1-AAA3 can optionally include where the flexible thermal conductive material is coupled to a heat pipe.

In Example AAA5, the subject matter of any one of Examples AAA1-AAA4 can optionally include where the activator is a link mechanism activator coupled to a link mechanism.

In Example AAA6, the subject matter of any one of Examples AAA1-AAA5 can optionally include where the link mechanism activator is a step motor.

What is claimed is:

1. An expandable heat sink for an electronic device, the expandable heat sink comprising:
flexible thermal conductive material; and
an activator, wherein the activator causes the expandable heat sink to be in a retracted configuration with a retracted height or in an expanded configuration with an expanded height, wherein the expanded height is greater than the retracted height.

2. The expandable heat sink of claim 1, wherein the retracted height is about three (3) millimeters and the expanded height is greater than about three (3) millimeters.

3. The expandable heat sink of claim 1, wherein the flexible thermal conductive material includes graphite sheets.

4. The expandable heat sink of claim 1, wherein the flexible thermal conductive material is coupled to a heat pipe.

5. The expandable heat sink of claim 1, wherein the activator is a link mechanism activator coupled to a link mechanism.

6. The expandable heat sink of claim 5, wherein the link mechanism activator is a step motor.

7. A device comprising:
one or more heat sources;
one or more fans; and
one or more expandable heat sinks, wherein each of the one or more expandable heat sinks includes:
flexible thermal conductive material; and
an activator, wherein the activator causes the expandable heat sink to be in a retracted configuration with a retracted height or in an expanded configuration with an expanded height, wherein the expanded height is greater than the retracted height.

8. The device of claim 7, wherein the retracted height is about three (3) millimeters and the expanded height is greater than about three (3) millimeters and less than about fifteen (15) millimeters.

9. The device of claim 7, wherein the flexible thermal conductive material includes graphite sheets.

10. The device of claim 7, wherein the flexible thermal conductive material includes fiber braids.

11. The device of claim 7, further comprising:
a cooling dock, wherein the cooling dock includes a cooling dock fan to move air through the one or more expandable heat sinks when the expandable heat sink is in the expanded configuration.

12. The device of claim 7, wherein the flexible thermal conductive material is coupled to a heat pipe.

13. The device of claim 7, wherein the activator is a link mechanism activator coupled to a link mechanism.

14. The device of claim 13, wherein the link mechanism activator is a step motor.

15. A method for expanding and retracting an expandable heat sink in an electronic device, the method comprising:
activating an activator to cause the expandable heat sink to be in an expanded configuration; and
deactivating the activator to cause the expandable heat sink to be in a retracted configuration, wherein the expandable heat sink includes flexible thermal conductive material.

16. The method of claim 15, wherein a retracted height of the expandable heat sink in the retracted configuration is about three (3) millimeters and an expanded height of the expandable heat sink in the expanded configuration is greater than about three (3) millimeters.

17. The method of claim 15, wherein the flexible thermal conductive material includes graphite sheets.

18. The method of claim 15, wherein the flexible thermal conductive material is coupled to a heat pipe.

19. The method of claim 15, wherein the activator is a link mechanism activator coupled to a link mechanism.

20. The method of claim 19, wherein the link mechanism activator is a step motor.
